(19) United States
(12) Patent Application Publication
(10) Pub. No.: US 2011/0291022 A1
(43) Pub. Date: Dec. 1, 2011

(54) Post Implant Wafer Heating Using Light

(75) Inventors: William D. Lee, Newburyport, MA (US); Marvin Farley, Ipswich, MA (US); William DiVergilio, Cambridge, MA (US)

(73) Assignee: Axcelis Technologies, Inc., Beverly, MA (US)

(21) Appl. No.: 12/944,407

(22) Filed: Nov. 11, 2010

Related U.S. Application Data
(60) Provisional application No. 61/349,547, filed on May 28, 2010.

(51) Int. Cl. H01J 37/20; H01J 37/18; H01J 37/08

(52) U.S. Cl. 250/453.11; 250/492.2; 250/492.21; 250/492.2

(57) ABSTRACT

An ion implantation system, method, and apparatus for abating condensation in a cold ion implant is provided. An ion implantation apparatus is configured to provide ions to a workpiece positioned in a process chamber. A sub-ambient temperature chuck supports the workpiece during an exposure of the workpiece to the plurality of ions. The sub-ambient temperature chuck is further configured to cool the workpiece to a processing temperature, wherein the process temperature is below a dew point of an external environment. A load lock chamber isolates a process environment of the process chamber from the external environment. A light source provides a predetermined wavelength of electromagnetic radiation to the workpiece concurrent with the workpiece residing within the load lock chamber, wherein the predetermined wavelength or range of wavelengths is associated with a maximum radiant energy absorption range of the workpiece, wherein the light source is configured to selectively heat the workpiece.

### REFERENCE TO RELATED APPLICATION

This application claims priority to and the benefit of U.S. Provisional Application Ser. No. 61/349,547 which was filed May 28, 2010, entitled Active Dew Point Sensing and Load Lock Venting to Prevent Condensation on Workpieces, the entirety of which is hereby incorporated by reference as if fully set forth herein.

### TECHNICAL FIELD

The present invention relates generally to ion implantation systems, and more specifically to preventing condensation from forming on a workpiece in an ion implantation system.

### BACKGROUND

Electrostatic clamps or chucks (ESCs) are often utilized in the semiconductor industry for clamping workpieces or substrates during plasma-based or vacuum-based semiconductor processes such as ion implantation, etching, chemical vapor deposition (CVD), etc. Clamping capabilities of the ESCs, as well as workpiece temperature control, have proven to be quite valuable in processing semiconductor substrates or wafers, such as silicon wafers. A typical ESC, for example, comprises a dielectric layer positioned over a conductive electrode, wherein the semiconductor wafer is placed on a surface of the ESC (e.g., the wafer is placed on a surface of the dielectric layer). During semiconductor processing (e.g., ion implantation), a clamping voltage is typically applied between the wafer and the electrode, wherein the wafer is clamped against the chuck surface by electrostatic forces.

For certain ion implantation processes, cooling the workpiece via a cooling of the ESC is desirable. At colder temperatures, however, condensation can form on the workpiece, or even freezing of atmospheric water on the surface of the workpiece can occur, when the workpiece is transferred from the cold ESC in the process environment (e.g., a vacuum environment) to an external environment (e.g., higher pressure, temperature, and humidity). For example, after an implantation of ions into the workpiece, the workpiece is typically transferred into a load lock chamber, and the load lock chamber is subsequently is vented. When the load lock chamber is opened to remove the workpiece therefrom, the workpiece is typically exposed to ambient atmosphere (e.g., warm, “wet” air), wherein condensation can occur. The condensation can deposit particles on the workpiece, and/or leave residues on the workpiece that can have adverse effects on front side particles (e.g., on active areas), and can lead to defects and production losses.

Therefore, a need exists in the art for an apparatus, system, and method for mitigating condensation on a workpiece when transferred from a cold environment to a warmer environment.

### SUMMARY

The present invention overcomes the limitations of the prior art by providing a system, apparatus, and method for abating condensation on a workpiece in a chilled ion implantation system. Accordingly, the following presents a simplified summary of the disclosure in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

In accordance with the present disclosure, an ion implantation system for implanting ions into a cold workpiece is provided. The ion implantation system, for example, comprises an ion implantation apparatus configured to provide a plurality of ions to a workpiece positioned in a process chamber. A sub-ambient temperature chuck, such as a cryogenically cooled electrostatic chuck, is configured to support the workpiece within the process chamber during an exposure of the workpiece to the plurality of ions. The cryogenic chuck is further configured to cool the workpiece to a processing temperature, wherein the process temperature is below a dew point of an external environment.

According to one aspect, a load lock chamber is operably coupled to the process chamber and configured to isolate a process environment associated with the process chamber from the external environment. The external environment, for example, is thus at an external temperature that is greater than the processing temperature. The load lock chamber further comprises a workpiece support configured to support the workpiece during a transfer of the workpiece between the process chamber and the external environment.

A light source configured to provide a predetermined wavelength or spectrum of electromagnetic radiation to the workpiece concurrent with the workpiece residing within the load lock chamber is further provided. According to the disclosure, the predetermined wavelength or range of wavelengths is associated with a maximum radiant energy absorption range of the workpiece, wherein the light source is configured to selectively heat the workpiece.

The above summary is merely intended to give a brief overview of some features of some embodiments of the present invention, and other embodiments may comprise additional and/or different features than the ones mentioned above. In particular, this summary is not to be construed to be limiting the scope of the present application. Thus, to the accomplishment of the foregoing and related ends, the invention comprises the features hereinafter described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a block diagram of an ion implantation system according to several aspects of the present disclosure.

FIG. 2 illustrates an exemplary graph of optical properties of a silicon wafer as a function of the wavelength of light.

FIG. 3 illustrates a methodology for abating condensation in a cold implantation of ions into a workpiece, according to still another aspect.

### DETAILED DESCRIPTION

The present disclosure is directed generally toward a system, apparatus, and method for abating condensation on a workpiece in an ion implantation system. Accordingly, the present invention will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessary to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features or circuits in one embodiment, and may also or alternatively be fully or partially implemented in a common feature or circuit in another embodiment. For example, several functional blocks may be implemented as software running on a common processor, such as a signal processor. It is further to be understood that any connection which is described as being wire-based in the following specification may also be implemented as a wireless communication, unless noted to the contrary.

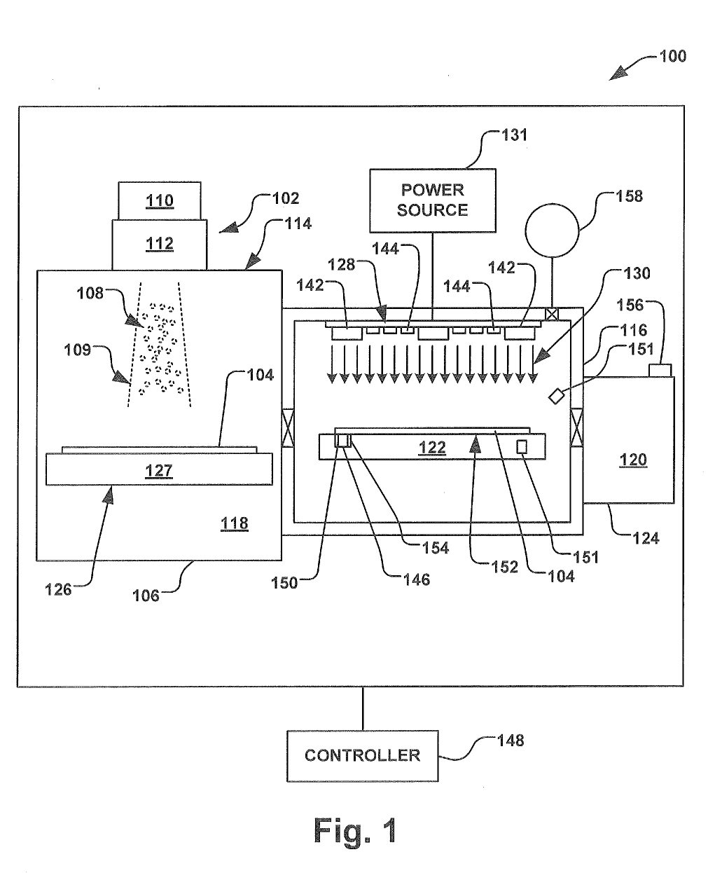

Referring now to the figures, FIG. 1 illustrates an exemplary ion implantation system 100. The ion implantation system 100, for example, comprises an ion implantation apparatus 102 configured to provide a plurality of ions 108 to a workpiece 104 (e.g., a semiconductor wafer, display panel, etc.) positioned in a process chamber 106. In one example, the ion implantation apparatus 102 is configured to form an ion beam 109, wherein the ion implantation apparatus comprises an ion source 110 configured to provide a beam of ions to a beamline assembly 112, wherein the beamline assembly is further configured to mass analyze the beam of ions, and to consequently provide the ion beam 109 to an end station 114 comprising the process chamber 106. Alternatively, the ion implantation apparatus 102 comprises a plasma chamber (not shown) or any other apparatus configured to implant or provide a plurality of ions 108 to a workpiece 104, and all such ion implantation apparatus configurations are contemplated as falling within the scope of the present disclosure.

A load lock chamber 116 is operably coupled to the process chamber 106, wherein the load lock chamber is configured to isolate a process environment 118 (e.g., a substantially dry vacuum environment) associated with the process chamber from an external environment 120, and further provides for a transfer of workpieces 104 into and out of the process environment without compromising the vacuum or pressure quality within the process environment. The load lock chamber 116, for example, comprises a workpiece support 122 configured to support the workpiece 104 during a transfer of the workpiece between the process chamber 106 and the external environment 120.

The workpieces 104, for example, travel between a FOUP 124 (e.g., a unit configured to carry the workpieces in the external environment 120) and the load lock chamber 116. The external environment 124 in which the FOUP 124 carries workpieces is in an ambient atmosphere that can have a relatively high dew point, depending on various environment factors, such as weather conditions, room ventilation, season, etc.

The ion implantation apparatus 102 of the present disclosure is configured to implant the plurality of ions 108 into the workpiece 104 at a low process temperature (e.g., any temperature below a dew point temperature of the external environment 120). Condensation has a tendency to form on a workpiece 104, however, if the workpiece is transferred from the implantation system to the external environment 120 when the workpiece is cooler than an ambient dew point in the external environment. If the temperature of the workpiece 104 is below the freezing point of water, for example, the workpiece will further develop frost upon being exposed to ambient water in the air (e.g., humidity) of the external environment 120.

In accordance with one example, a sub-ambient temperature chuck 126 is provided, wherein the sub-ambient temperature chuck is configured to support the workpiece 104 within the process chamber 106 during an exposure of the workpiece to the plurality of ions 108. The sub-ambient temperature chuck 126, for example, comprises an electrostatic chuck 127 and is configured to cool or chill the workpiece 104 to a processing temperature below the ambient dew point (also called dew point temperature) of the external environment 120, such as approximately −40 degrees C. As such, the processing temperature is significantly lower than the external temperature of the external environment 120, and without warming of the workpiece 104 prior to exposure to the external environment, condensation may form thereon, thus potentially deleteriously affecting the workpiece.

Accordingly, in accordance with the present disclosure, a light source 128 is associated with the load lock chamber 116, wherein the light source is configured to provide one or more predetermined wavelengths (e.g., a singular wavelength, plurality of wavelengths, or a wavelength spectrum) of electromagnetic radiation 130 to the workpiece 104 concurrent with the workpiece residing within the load lock chamber. The predetermined wavelength or wavelength spectrum of the electromagnetic radiation 130, in accordance with the present disclosure, is associated with a maximum radiant energy absorption range of the workpiece 104, wherein the light source 128 is configured to selectively heat the workpiece within the load lock chamber 116 prior to being exposed to the external environment 120. The light source 128 is further powered by a controllable power source 131.

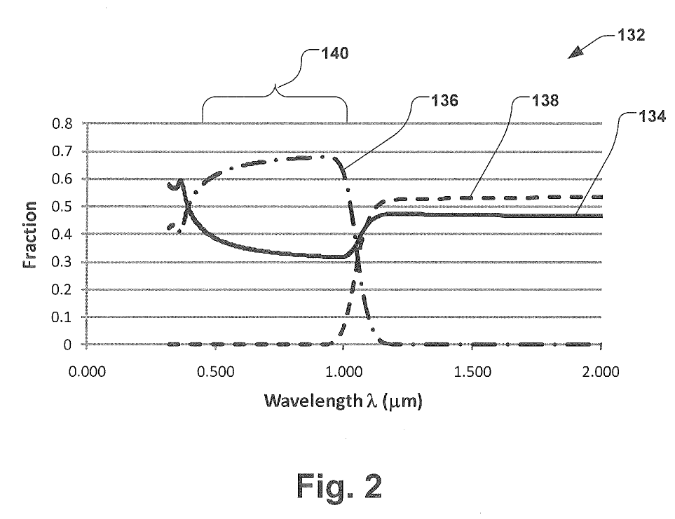

FIG. 2 illustrates an example spectral distribution 132 of an example workpiece 104 of FIG. 1, wherein the workpiece is comprised of a 0.75 mm thick, 300 mm diameter silicon wafer having a thermal mass of approximately 90 joules/degrees C. In the spectral distribution 132 of FIG. 2, for example, reflected radiation 134, absorbed radiation 136, and transmitted radiation 138 is shown, wherein a maximum radiant energy absorption range 140 is illustrated as being within 0.4 and 1.1 um. Within the maximum radiant energy absorption range 140, approximately 50%-60% of the electromagnetic radiation 130 from the light source 128 is absorbed by the workpiece 104 of FIG. 1.

In accordance with the present disclosure, the light source 128 of FIG. 1, for example, is thus selected so as to provide electromagnetic radiation 130 at one or more predetermined wavelengths, predominantly within the maximum radiant energy absorption range 140. In the above example, the light source 128 is selected to comprise one or more halogen lamps 142, wherein the halogen lamps emit a great amount of electromagnetic energy within the maximum radiant energy absorption range 140. Alternatively or in combination with the halogen lamps 142, the light source 128 comprises an array of light emitting diodes 144 selected to emit electromagnetic radiation 130 having radiation wavelength(s) substantially corresponding to the maximum radiant energy absorption range 140 of FIG. 2, for example. The desired predetermined wavelength(s) or wavelength spectrum of the light source 128, for example, are predominantly in one or more of the infrared, visible, and ultraviolet light spectrum. Various other light sources 128, either alone, or in combination, are further contemplated, such as one or more arc discharge lamps, vapor discharge lamps, incandescent lamps, fluorescence lamps, and the like, and all such light sources are contemplated as falling within the scope of the present invention.

In accordance with another aspect, the load lock chamber 116 of FIG. 1 further comprises a workpiece temperature monitoring device 146 configured to measure a temperature of the workpiece 104. A controller 148, for example, is further provided and configured to control the power source 131 of the light source 128, and thus control an amount of the electromagnetic radiation 130 emitted from light source, wherein the control is further based, at least in part, on data from the workpiece temperature monitoring device 146. The workpiece temperature monitoring device 146, for example, comprises one or more of a thermocouple 150 and an optical temperature measurement apparatus 151 associated with a surface 152 of the workpiece support 122. A shroud 154, for example, is further associated with the thermocouple 150 or workpiece temperature monitoring device 146, wherein the thermocouple or workpiece temperature monitoring device is generally shielded from the predetermined wavelength of electromagnetic radiation 130 when the workpiece 104 resides on the workpiece support 122.

According to another example, a secondary monitoring device 156 is provided, wherein the secondary monitoring device is configured to measure at least the external temperature of the external environment 120. The secondary monitoring device 156, in another example, is further configured to measure relative humidity (RH) in the external environment 120. Accordingly, the controller 148 is configured to determine a temperature of the workpiece 104 at which condensation will not form on the workpiece when the workpiece is transferred from the load lock chamber 116 to the external environment 120, wherein the determination is made based, at least in part, on data from the workpiece temperature monitoring device 146 and secondary temperature monitoring device 156.

In accordance with yet another example, a gas and/or vacuum source 158 is provided in selective fluid communication with the load lock chamber 116, wherein the gas and/or vacuum source is configured to provide a dry gas and/or vacuum to the load lock chamber.

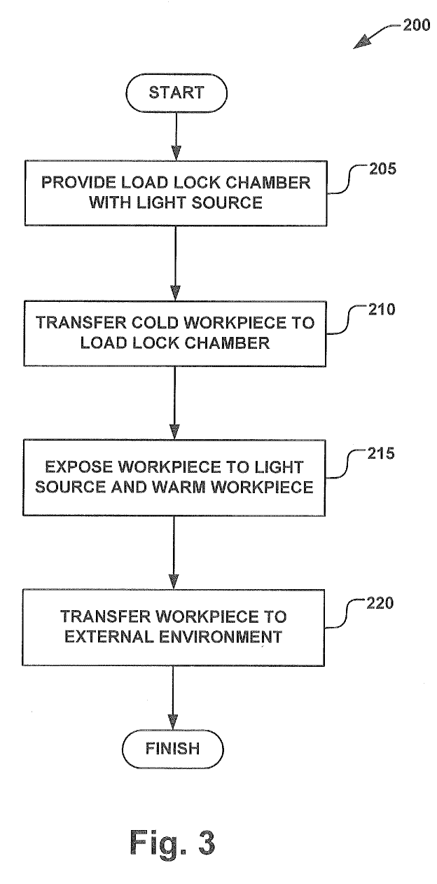

In accordance with another exemplary aspect of the invention, FIG. 3 illustrates an exemplary method 200 for abating condensation on a workpiece in an ion implantation system. It should be noted that while exemplary methods are illustrated and described herein as a series of acts or events, it will be appreciated that the present invention is not limited by the illustrated ordering of such acts or events, as some steps may occur in different orders and/or concurrently with other steps apart from that shown and described herein, in accordance with the invention. In addition, not all illustrated steps may be required to implement a methodology in accordance with the present invention. Moreover, it will be appreciated that the methods may be implemented in association with the systems illustrated and described herein as well as in association with other systems not illustrated.

The method 200 of FIG. 6 begins at act 205, wherein a load lock chamber is provided having a light source configured to emit electromagnetic radiation at a predetermined wavelength. It should be noted that the predetermined wavelength is understood to comprise both a single wavelength of electromagnetic radiation, as well as a plurality or range of wavelengths of electromagnetic radiation or light. The predetermined wavelength is selected based, at least in part, on a maximum absorptive range of electromagnetic radiation associated with the workpiece.

In act 210, a workpiece is transferred from a process environment to the load lock chamber. The workpiece, for example, is transferred from a sub-ambient temperature chuck, wherein the workpiece has undergone a cold ion implantation, and is at a process temperature or first predetermined temperature that is lower than the dew point of the environment. In act 215, the workpiece is exposed to the light source, therein warming the workpiece to a second predetermined temperature. The second predetermined temperature, for example, is greater than the dew point temperature of an external environment. In act 220, the workpiece is transferred from the load lock chamber to the external environment, wherein condensation is abated by raising the temperature of the workpiece via the light source.

According to one example, a temperature of the workpiece is measured concurrent with exposing the workpiece to the light source in act 215. Accordingly, the workpiece is transferred to the external environment from the load lock chamber in act 220 after measured temperature meets or exceeds the second predetermined temperature.

Although the invention has been shown and described with respect to a certain embodiment or embodiments, it should be noted that the above-described embodiments serve only as examples for implementations of some embodiments of the present invention, and the application of the present invention is not restricted to these embodiments. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application. Accordingly, the present invention is not to be limited to the above-described embodiments, but is intended to be limited only by the appended claims and equivalents thereof.

What is claimed is:

1. An ion implantation system, comprising:
an ion implantation apparatus configured to provide a plurality of ions to a workpiece positioned in a process chamber;
a sub-ambient temperature chuck configured to support the workpiece within the process chamber during an exposure of the workpiece to the plurality of ions, wherein the sub-ambient temperature chuck is further configured to cool the workpiece to a processing temperature;
a load lock chamber operably coupled to the process chamber and configured to isolate a process environment associated with the process chamber from an external environment, wherein the external environment is at an external temperature that is greater than the processing temperature, and wherein the load lock chamber comprises a workpiece support configured to support the workpiece during a transfer of the workpiece between the process chamber and the external environment; and
a light source configured to provide one or more predetermined wavelengths of electromagnetic radiation to the workpiece concurrent with the workpiece residing within the load lock chamber, wherein the one or more predetermined wavelengths are associated with a maximum radiant energy absorption range of the workpiece, wherein the light source is configured to selectively heat the workpiece.

2. The system of claim 1, wherein the light source comprises one or more of a halogen lamp, arc discharge lamp, vapor discharge lamp, incandescent lamp, fluorescent lamp, and an array of light emitting diodes.

3. The system of claim 1, wherein the process environment is generally at a vacuum, and wherein the external environment is at generally atmospheric pressure.

4. The system of claim 1, wherein the one or more predetermined wavelengths are in one or more of the infrared, visible, and ultraviolet light spectrum.

5. The system of claim 1, further comprising a transfer apparatus configured to transfer the workpiece between the process chamber, load lock chamber, and external environment.

6. The system of claim 1, wherein the ion implantation apparatus comprises:
an ion source configured to form an ion beam;
a beamline assembly configured to mass analyze the ion beam; and
an end station comprising the process chamber.

7. The system of claim 1, wherein the sub-ambient temperature chuck comprises an electrostatic chuck configured to chill the workpiece below an ambient dew point of the external environment.

8. The system of claim 1, wherein the load lock chamber further comprises a workpiece temperature monitoring device configured to measure a temperature of the workpiece.

9. The system of claim 8, wherein the external environment has a higher dew point temperature than the process environment, the system further comprising:
a secondary monitoring device, wherein the secondary monitoring device is configured to measure at least the external temperature of the external environment; and
a controller configured to determine a temperature of the workpiece at which condensation will not form on the workpiece when the workpiece is transferred from the load lock chamber to the external environment, wherein the determination is made based, at least in part, on data from the workpiece temperature monitoring device and secondary temperature monitoring device.

10. The system of claim 9, wherein the secondary monitoring device is further configured to measure relative humidity in the external environment.

11. The system of claim 8, wherein the a workpiece temperature monitoring device comprises a thermocouple associated with a surface of the workpiece support.

12. The system of claim 8, wherein the workpiece temperature monitoring device comprises an optical temperature measurement apparatus associated with a surface of the workpiece support.

13. The system of claim 8, wherein the workpiece support comprises a shroud associated with the workpiece temperature monitoring device, wherein the workpiece temperature monitoring device is generally shielded from the one or more predetermined wavelengths of light when the workpiece resides on the workpiece support.

14. The system of claim 8, further comprising a controller configured to determine a temperature of the workpiece at which condensation will not form on the workpiece when the workpiece is transferred from the load lock chamber to the external environment, wherein the determination is made based, at least in part, on data from the workpiece temperature monitoring device.

15. The system of claim 14, wherein the controller is further configured to control an amount of the electromagnetic radiation emitted from light source, wherein the control is further based on the data from the workpiece temperature monitoring device.

16. The system of claim 1, further comprising a gas source in fluid communication with the load lock chamber, wherein the gas source is configured to provide a dry gas to the load lock chamber.

17. An ion implantation condensation abatement apparatus, comprising:
a sub-ambient temperature electrostatic chuck, configured to cool a workpiece to a predetermined temperature below an external temperature of an external environment during an implantation of ions into the workpiece;
a load lock chamber, wherein the load lock chamber is configured to receive the workpiece from a process chamber and to transfer the workpiece to the external environment, and wherein the load lock chamber comprises a light source configured to provide one or more predetermined wavelengths of electromagnetic radiation to the workpiece concurrent with the workpiece residing within the load lock chamber, and wherein the one or more predetermined wavelengths are associated with a maximum radiant energy absorption range of the workpiece.

18. The ion implantation condensation abatement apparatus of claim 17, wherein the light source is configured to heat the workpiece to above an ambient dew point of the external environment within a predetermined amount of time.

19. The ion implantation condensation abatement apparatus of claim 17, wherein the light source comprises one or more of a halogen light source, an array of light emitting diodes, an arc discharge lamp, an incandescent lamp, a fluorescent lamp, and a vapor lamp.

20. The ion implantation condensation abatement apparatus of claim 17, further comprising a workpiece temperature monitoring device configured to measure a temperature of the workpiece concurrent with the workpiece residing within the load lock chamber.

21. The ion implantation condensation abatement apparatus of claim 17, further comprising a controller configured to control one or more of the light source and a duration of exposure of the workpiece to the light source, wherein the control is based, at least in part, on an ambient dew point of the external environment.

22. A method for preventing condensation on a workpiece, the method comprising:
cooling a workpiece to a first predetermined temperature in a process environment in a cold implant ion implantation system;
providing a load lock chamber having a light source configured to emit electromagnetic radiation at one or more predetermined wavelengths, wherein the one or more predetermined wavelengths are selected based, at least in part, on a maximum absorptive range of electromagnetic radiation associated with the workpiece;
transferring the workpiece from the process environment to a load lock chamber;
exposing the workpiece to the light source, therein warming the workpiece to a second predetermined temperature that is greater than an ambient dew point of an external environment; and
transferring the workpiece from the load lock chamber to the external environment.

23. The method of claim 22, further comprising measuring the temperature of the workpiece concurrent with exposing the workpiece to the light source, and transferring the workpiece from the load lock chamber to the external environment after the second predetermined temperature has been reached by the workpiece.

24. The method of claim 22, wherein the electromagnetic radiation comprises one or more of infrared, visible, and ultraviolet light.

25. The method of claim 22, wherein the light source comprises one or more of a halogen lamp, arc discharge lamp, vapor discharge lamp, incandescent lamp, fluorescent lamp, and an array of light emitting diodes.

26. The method of claim 22, wherein the first predetermined temperature is below the dew point temperature of the external environment.

27. The method of claim 22, wherein the one or more predetermined wavelengths comprises a spectrum of wavelengths.
